(19) United States
(12) Patent Application Publication
(10) Pub. No.: US 2012/0305298 A1
(43) Pub. Date: Dec. 6, 2012

(54) BUMP WITH NANOLAMINATED STRUCTURE, PACKAGE STRUCTURE OF THE SAME, AND METHOD OF PREPARING THE SAME

(75) Inventors: Ruoh-Huey Uang, Hsinchu County (TW); En-Yu Pan, Kaohsiung City (TW)

(73) Assignee: INDUSTRIAL TECHNOLOGY RESEARCH INSTITUTE, Hsinchu (TW)

(21) Appl. No.: 13/219,707

(22) Filed: Aug. 28, 2011

(30) Foreign Application Priority Data
May 31, 2011 (TW) 100119028

(51) Int. Cl. H05K 1/09; B23K 31/02; B23K 1/20; B32B 15/04; B32B 5/00

(52) U.S. Cl. 174/257; 428/457; 428/447; 428/220; 228/203; 228/205

(57) ABSTRACT

A bump with nanolaminated structure is provided. The bump with nanolaminated structure includes a bump, a nanolaminated structure and an organic layer. The nanolaminated structure is located on the bump. The organic layer is located between the bump and the nanolaminated structure. The organic molecular of the organic layer includes two terminal function groups, wherein a first terminal function group is bonded with a first metal atom of the bump and a second terminal function group is bonded with a second metal atom of the nanolaminated structure.

### CROSS-REFERENCE TO RELATED APPLICATION

This application claims the priority benefit of Taiwan application serial no. 100119028, filed on May 31, 2011. The entirety of the above-mentioned patent application is hereby incorporated by reference herein and made a part of this specification.

### TECHNICAL FIELD

The disclosure relates to a bump, a package structure of the same, and a manufacturing method of the same, more particularly to a bump with a nanolaminated structure, a package structure of the same, and a manufacturing method of the same.

### BACKGROUND

Currently, the bonding process for a three dimensional integrated circuit (3D IC) is classified into two main types, which are tin soldering and direct copper bump thermal compression bonding. The advantage of tin solder bonding includes providing lower external pressure and bonding temperature than those required for thermal compression bonding. Typically, a tin solder is applied to a SnAgCu ternary alloy bump. The melting point of a tin solder is about 220° C., and an external pressure required for tin solder bonding is about several tens MPa. However, the biggest problem of employing a ternary alloy in a bump forming process is that electroplating is not applicable in forming a ternary alloy. Further, the smallest dimension of a structure can be formed by a printing process is about 25 μm. Therefore, to fabricate a 10 μm bump, some not only other bonding methods, such as immersion bumping, can fabricate to 10 μm bump but the fabrication temperature must be raised to about 250° C. Another approach for fabricating a bump is the application of a binary alloy. However, the melting point of a copper tin alloy is at least 230° C., and the bonding temperature of the binary or ternary alloy bump is at least 250° C. or above. Moreover, the resistance of a tin solder is higher (10 times of copper), and the formation of inter-metallic compounds also affect the reliability of the device.

Another bonding process is the direct copper bump thermal compression bonding, in which a metal is directly bonded on the copper bump. Accordingly, the resistance is low and the problem of inter-metallic compounds is also precluded. However, the process must be performed in a vacuum environment, mass production is thereby difficult. Further, the process must also be performed under a load (a large applied pressure of 100 MPa) at an elevated temperature (a bonding temperature of about 350° C. to 400° C.). Consequently, the bonding of thin wafers often results with the generation of thermal stress and cracks on the wafers.

To lower the applied pressure and the bonding temperature required in thermal compression bonding process, a plasma treatment process is performed to roughen the surface of the bump. However, a metal material is different from an organic material, and the surface roughen effect created by physical bombardment (Ar) is limited and the appearance of the roughened surface is also difficult to control. Further, no chemical plasma etching process is known to be appropriate for a typical copper bump. In simple terms, it is difficult to obtain a regular and uniform nanostructure surface using plasma etching.

A nanostructure has the characteristics of high surface energy, large contact area, etc. As described in a publication, an object of several kilograms may bond to a wall using carbon nanotubes without the application of a chemical adhesive substance. If the surface of a bump has a nanostructure, even in the absence of excessive heating and pressurization, the upper and lower bumps are tightly bonded together by diffusion bonding of the nanostructured metal atoms. Another publication revals that two pieces of stainless steel are completely bonded without any gap at the bonding interfaces by using Ni nanoparticles under a low pressure. Moreover, nanogold wires can be diffusion bonded in an acid solution at a temperature of 270° C., which is lower than a typical gold diffusion bonding temperature (430° C.). However, with the current process, it is not easy to form a nanostructure directly on a bump. Hence, the development of the technique using nanostructure for bonding is limited.

According to the current nanometal technique, nanometals are directly positioned on a substrate or a bump. To avoid the aggregation of nanometals, a large amount of “protecting agent” or “chelating agent” is applied to the peripheries of the nanometals. However, the application of a large amount of “protecting agent” or “chelating agent” would lead to the formation of voids in the package structure in the subsequent process.

### SUMMARY

An exemplary embodiment of the disclosure provides a bump having a nanolaminated structure, wherein by applying organic molecules having functional groups, metal ions are affixed to one of the functional groups through chemical bonding or physical bonding (such as, coordinate bonding, van der waals bonding, or hydrogen bonding) and are reduced to a metal. Ultimately, a nanolaminated structure is assembled on the bump.

An exemplary embodiment of the disclosure provides a package structure, wherein the nanometal and the bump have desirable bonding properties.

An exemplary embodiment of the disclosure provides a fabrication method of a bump having a nanolaminated structure, wherein an organic layer is applied to form a nanolamianted structure on a bump.

An exemplary embodiment of the disclosure provides a bump having a nanolaminated structure. The bump having a nanolaminated structure includes at least a bump an organic layer, and a nanolaminated structure. The nanolaminated structure is formed with a plurality of nanometals on the bump. The organic layer is contiguous to the bump and the nanolaminated structure. The structure of the organic layer is G₁-R-G₂, wherein R is alkylene with less than 10 carbons; G₁ is a first functional group, which forms a first metal bond with the bump; and G₂ is a second functional group, which forms a second metal bond with the nanolaminated structure.

An exemplary embodiment of the disclosure provides a package structure, and the package structure includes a first member, a first bump, a first nanolaminated layer, a first organic layer fragment, a second member, a second bump, and a second nanolaminated layer. The first bump is configured on the first member. The first nanolaminated layer is configured on and is electrically connected with the first bump. The first organic layer fragment is configured between the first bump and the first nanolaminated layer, and the structure of the first organic layer G₁-R-G₂, wherein R is alkylene with less than 10 carbons; G₁ is a first functional group, which includes one of the following groups:

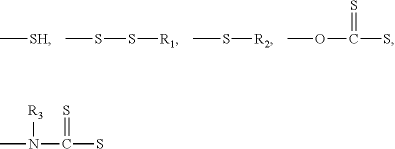

wherein R₁, R₂ and R₃ are each independently an alkyl with or without a substituted group, the substituted group includes, for example, carboxyl (—COOH), amino (—NH₂), amide (—CONH₂), cyano (—CN), —OH, or —Si—OH. The second member and the first member are configured opposite to each other. The second bump is configured on the second member. The second nanolaminated layer is configured between and is electrically connected with the first nanolaminated layer and the second bump.

An exemplary embodiment of the disclosure provides a fabrication method of a bump having a nanolaminated structure, and the method includes providing a surface having at least a bump. Then, a first self-assembling step is performed to assemble an organic layer on the bump. The structure of the first organic layer is G₁-R-G₂, wherein R is alkylene with less than 10 carbons; G₁ is a first functional group and is bonded with the first metal atom of the bump, wherein the first functional group includes one of the following groups:

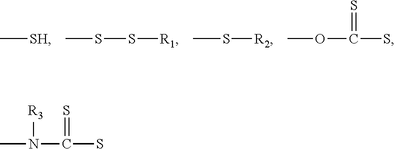

wherein R₁, R₂ and R₃ are each independently an alkyl with or without a substituted group, the substituted group includes, for example, carboxyl (—COOH), amino (—NH₂), amide (—CONH₂), cyano (—CN), —OH, —Si—OH or —Si(OCₓH₂ₓ₊₁)₃, wherein x is 1, 2, or 3. Thereafter, a second self-assembling step is performed, wherein the second metal ions are bonded on the bump through the organic layer. Then, a redox reaction is performed to reduce the second metal ions to a second metal to form a plurality of nanometals. The plurality of nanometals is stacked to form a nanolaminated structure.

According to an exemplary embodiment of the disclosure, by applying an organic layer with a bifunctional group, a plurality of nanolaminated structure (nanometals) is selectively self-assembled on the bump.

According to a package structure of an exemplary embodiment of the disclosure, the nanolaminated structure and the bump include organic layer fragments therebetween. Nevertheless, bonding properties of the nanolaminated metals and the bump are desirable.

According to a fabrication method of a bump having a nanolaminated structure of an exemplary embodiment of the disclosure, a simple redox reaction is performed to reduce metal ions to a metal directly on a bump. Further, the size and the shape of the metal particles are adjustable to form a dense nanostructure on the bump.

The invention and certain merits provided by the invention can be better understood by way of the following exemplary embodiments and the accompanying drawings, which are not to be construed as limiting the scope of the invention.

### BRIEF DESCRIPTION OF THE DRAWINGS

FIG. 1 is a schematic diagram of a bump with a nanolaminated structure according to an exemplary embodiment of the invention.

FIG. 2 is a flow chart of steps in exemplary processes that may be used in the fabrication of a bump with a nanolaminated structure according to an exemplary embodiment of the invention.

FIGS. 3A to 3D are cross-sectional views for schematically showing the steps of fabricating a bump with a nanolaminated structure according to an exemplary embodiment of the disclosure.

FIGS. 4A to 4B are schematic cross-sectional views of a package process according to an exemplary embodiment of the disclosure.

FIGS. 5A to 5B are spectra of the ESCA analysis results respectively showing the copper analytic curve and the sulfur analytic curve according an exemplary embodiment of the disclosure.

FIGS. 6 to 10 are scanning electron microscope pictures of the nanoparticles synthesized according Examples 1-5 of the disclosure.

FIGS. 11A and 11B are scanning electron microscope pictures of the nanoparticles synthesized according Example 6 of the disclosure.

FIG. 12 is a scanning electron microscope picture of the nanoparticles synthesized according Example 7 of the disclosure.

FIGS. 13 and 14 are scanning electron microscope pictures respectively showing the application of various amounts of the protecting agent for placing the nanoparticles directly on a substrate according to the prior art.

### DETAILED DESCRIPTION OF DISCLOSED EMBODIMENTS

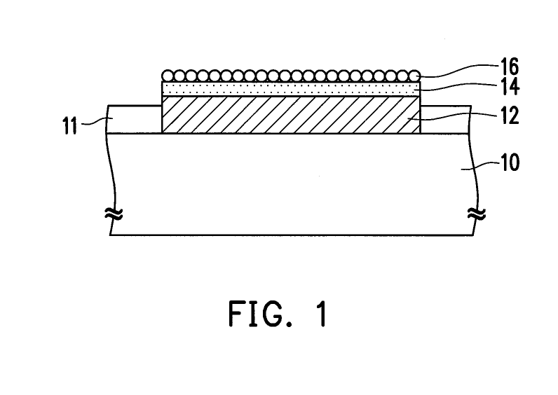

FIG. 1 is a schematic diagram of a bump with a nanolaminated structure according to an exemplary embodiment of the invention.

Referring to FIG. 1, a bump 12 with a nanolaminated structure includes a bump 12, a plurality of nanolaminated structures 16, and an organic layer 14. The bump 12 is configured on a surface of a member 10. The surface of the member 10 may be a planar surface or a curved surface. The member 10 with a planar surface is, for example, a semiconductor substrate, a glass substrate, a metal substrate, a resin substrate, or other possible substrates or carriers. Electronic components may form on the above substrate or carrier. A member 10 with a curved surface is, for example, a nanoparticle thereon. The material of the bump 12 includes, for example, a first metal, such as, copper, gold, nickel, or the alloys or composites thereof. In one exemplary embodiment, the size of the bump 12 is, for example, 100 nm to 1 micron.

The plurality of nanolaminated structures 16 is configured on the bump 12. The material of the nanolaminated structures 16 includes a second metal, such as silver, gold, copper, nickel, platinum, or the alloys or composites thereof. During the package process, excessively high pressurization or excessively high temperature is not required for diffusion bonding of the metal atoms of the nanolaminated structures 16 to tightly bond the upper and lower bumps together because of the use of the nanolaminated structures 16. It is also not necessary for each nanometal of the nanolaminated structures 16 applied in diffusion bonding to have a very small particle diameter. Further, during the fabrication process, an excessive amount of the protecting agent for enclosing the surface of each nanolaminated structure 16 is not required and the total thickness of the nanolaminated structure 16 does not have to be too large. In one exemplary embodiment, the nanometal of each nanolaminated structure 16 has a dimension of about 30 nanometer to 200 nanometer. The nanometals of the nanolaminated structures 16 include nanowires, ball-shaped structures, flake-shaped structures, nanorods, nanocubes, structures with irregular shapes, or a combination thereof. The nanometals are stacked into two to three layers, and the thickness of each layer is less than 1 micron, for example, 100 nanometer to 1 micron.

The above organic layer 14 is configured between and bonded with the bump 12 and the nanolaminated structures 16. More specifically, the organic layer 14 includes a monolayer of organic molecules with bifunctional groups, and the structure thereof may be represented as G₁-R-G₂, wherein R is the backbone of the organic layer and is an alkylene group (CH₂)ₙ with a carbon number less than 10, and n is a natural number less than 10. When n is a natural number less than 10, G₁-R-G₂ degrades during thermal compression bonding to form small molecule fragments or to vanish. The bump 12 and the nanolaminated structures 16 are thus in contact, while the contact resistance between the bump 12 and the nanolaminated structures 16 is unaffected. However, when R of G₁-R-G₂ has a carbon number greater than 10, G₁-R-G₂ does not degrade into small molecule fragments or vanish during thermal compressing bonding process. Instead, the organic layer 14 remains between the bump 12 and the nanolaminated structure 16, causing the bump 12 and the nanolaminated structure 16 to be in poor or no contact and the contact resistance is affected. G₁ is the first functional group, which may have a chemical bonding or physical bonding (such as coordinate bond, van der waals bond, or hydrogen bond) with the first metal of the bump 12. G₂ is the second functional group, which may have a chemical bonding or physical bonding (such as coordinate bond, van der waals bond, hydrogen bond) with the second metal of the nanolaminated layer structures 16. The first functional group G₁ includes one of the following groups:

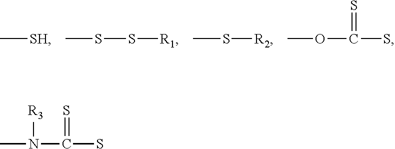

wherein R₁, R₂ and R₃ are each independently an alkyl with or without a substituted group, and the substituted group includes, for example carboxyl (—COOH), amino (—NH₂), amide (—CONH₂), cyano (—CN), —OH, —Si—OH, or —Si(OCₓH₂ₓ₊₁)₃, wherein x is a whole number ranging from 1 to 3. The second functional group G₂ may alter the wetting and interfacial properties of the backbone R, and the second functional group G₂ includes —COOH, —NH₂, —CONH₂, —CN, —OH, —Si—OH, —Si(OCₓH₂ₓ₊₁)₃, or —CHO, wherein x is 1, 2 or 3.

The organic layer 14 (G₁-R-G₂) includes HS—(CH₂)ₙ—COOH or HS—(CH₂)ₙ—Si(OCₓH₂ₓ₊₁)₃, wherein n is an integer from 1 to 10, x is 1, 2, or 3, OCₓH₂ₓ₊₁ is, for example, OCH₃, which can be totally or partially hydrolyzed into —OH. HS—(CH₂)ₙ—COOH is, for example, HS—C₃H₆—COOH. Alternatively speaking, G₁-R-G₂ includes, for example, alkanethiols, disulfides, dialkyl disulfides, dialkyl sulfides, alkylxanthates or dialkylthiocarbamates, and the terminal of the alkyl chain of the above-mentioned compounds is replaced by G₂.

The first metal of the bump 12 may be the same as or different from the second metal of the nanolaminated structures 16. In one exemplary embodiment, the first metal of the bump 12 is copper, while the second metal of the nanolaminated structures 16 is silver. The first functional group G₁ of the organic layer 14 includes, for example, a thiol group (—SH), the second functional group G₂ includes, for example, a carboxyl group (—COOH), an amino group (—NH₂), an amide group (—CONH₂) or a cyano group (—CN), a hydroxyl group (—OH), or a silicon hydroxyl group (—Si—OH). In another example, the first metal of the bump 12 is gold, the second metal of the nanolaminated structures 16 is nickel, and the first functional group G₁ is, for example, one of the following groups:

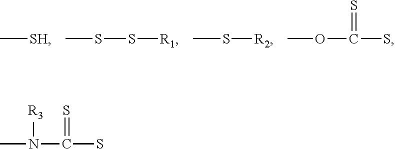

wherein R₁, R₂, and R₃ are defined as above, and will not be further reiterated herein. The second functional group G₂ is, for example, —COOH, —NH₂, —CONH₂, —CN, —OH, CHO or —Si—OH.

Examples of the organic layer 14 include:
HS(CH₂)₃COOH;
NH₂(CH₂)ₙSH, wherein n is a whole number ranging from 1 to 10; or
Si(OCH₃)₃(CH₂)₃SH, wherein Si—OCH₃ is totally or partially hydrolyzed into Si—OH.

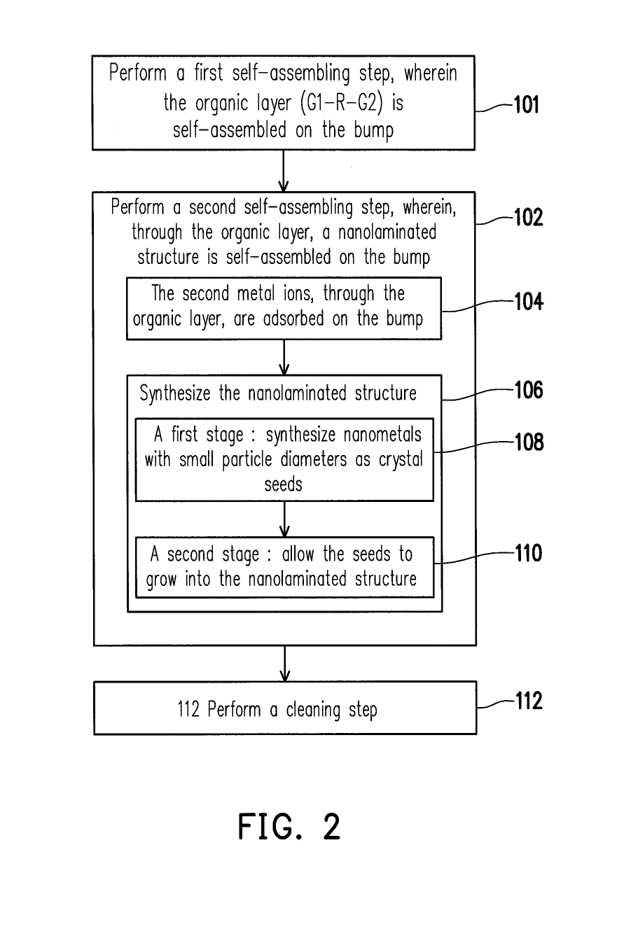

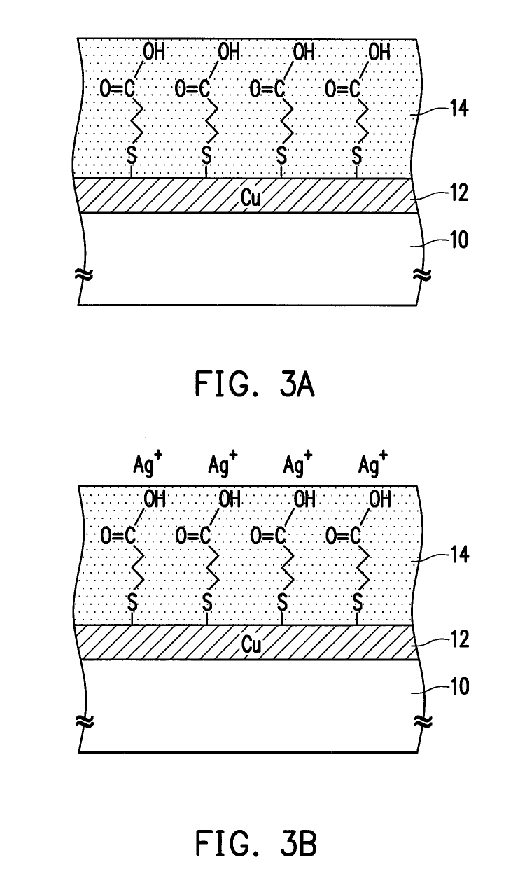

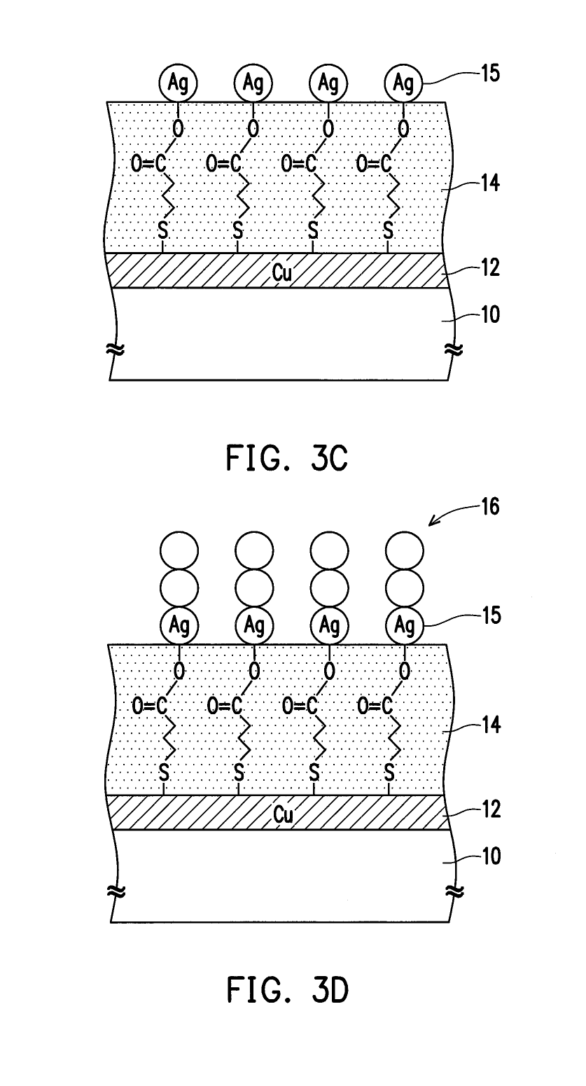

FIG. 2 is a flow chart of steps in exemplary processes that may be used in the fabrication of a bump with a nanolaminated structure according to an exemplary embodiment of the invention. FIGS. 3A to 3D are cross-sectional views for schematically showing the steps of fabricating a bump with a nanolaminated structure according to an exemplary embodiment of the disclosure.

Referring to both FIGS. 2 and 3A, in step 101, a self-assembling step is performed, wherein the organic layer (G₁-R-G₂) is self-assembled on the bump 12 of the member 10. The member 10 includes a bump 12 thereon, and the surrounding of the bump 12 is covered by the dielectric layer 11 (shown in FIG. 1). The materials of the member 10 and the bump 12 are similar to those discussed above. The material of the dielectric layer 11 includes silicon oxide or silicon nitride. The structure of the organic layer 14 is similar to that disclosed above, and the details thereof will not be further discussed herein. Since the first function group G₁ of the organic layer 14 is highly reactive with the first metal of the bump 12 and is not reactive with the dielectric layer 11, the first functional group of the organic layer 14 is coordinated bonded with the first metal atom of the bump 12 during the deposition of the organic layer 14. Hence, the organic layer 14 is selectively assembled on the bump 12 and is not deposited on the dielectric layer. To better understand the coordinated bonding situation in the exemplary embodiment, the first metal of the bump being copper and the organic layer being HS—C₂H₄—COOH, as shown in FIG. 3A, are used for illustration. It is noted that the exemplary embodiment is not intended to restrict the scope of the disclosure. The organic layer 14 is deposited on the bump (Cu) 12, the thiol group (—SH) of the organic layer 14 reacts with copper to form a Cu—S bond.

Thereafter, referring to FIGS. 2 and 3D, in step 102, a second self-assembling step is performed to form a dense nanolaminated structures 16 on the bump 12 through the organic layer 14, wherein metal ions are affixed to the organic layer 14 via chemical bonding or physical bonding, and a redox reaction is performed to reduce the metal ions to metal. Moreover, the size and the shape of the metal particles are controllable. The self-assembling step 102 includes step 104 and step 106. Referring to FIGS. 2 and 3D, in step 104, the member 10 with the already formed organic layer 14 is disposed in the solution containing the second metal ions, wherein the second metal ions is adsorbed on the bump 12 of the member 10 through the organic layer 14. Step 106 is a nanolaminated structure synthesis step, conducted subsequent to step 104. Step 106 includes two stages: stage 108 and stage 110. During the first stage 108, the metal particles, through the organic layer 14, are selectively assembled on the bump 12 to serve as crystal seeds. In the second stage 110, the metal particles 15 grow and are stacked to form the dense nanolaminated structures 16.

More specifically, in step 104, the member 10 with the already formed organic layer 14 is placed in a first solution containing second metal ions. The second metal ions in the first solution are adsorbed on the bump 12 of the member 10 through the organic layer 14. The second metal ions include, for example, silver ions, gold ions, copper ions, nickel ions, or platinum ions. In one exemplary embodiment, the second metal ions are silver ions, for example, the first solution containing the second metal ions further include the ingredients of sodium borohydride, silver nitrate, and sodium citrate. In the exemplary embodiment, as shown in FIG. 3B, the solution containing the second metal ions is silver nitrate, the second metal ions are silver ions (Ag⁺), and the second ions are adsorbed to the second functional group COOH of the organic layer.

In the first stage 108 of the synthesis of the nanolaminated structures 16, the second metal ions on the bump 12 are directly reduced with the reducing agent in the first solution to form second nanometal atoms with small particle diameters. Since the second nanometal atoms are highly reactive with the second function group of the organic layer 14 and are not reactive with the dielectric layer (not shown), a bonding is generated between the second nanometal atoms and the second functional group of the organic layer 14 to form crystal seeds 15. In one exemplary embodiment, the second metal ions are silver ions, the first solution containing the second metal ions also includes the ingredients of sodium borohydride, silver nitrate, and sodium citrate. Sodium borohydride reduces the silver ions of silver nitride to silver particles. In the exemplary embodiment as shown in FIG. 3C, silver ions in the first solution are reduced to silver particles and react with the second functional group (carboxyl group) of the organic layer 14 as shown in the following chemical formula to form the nanolaminated structures (as in Table 1):

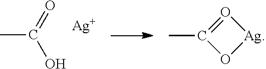

According to another exemplary embodiment, if a denser structure is desired, the second stage 110 of the step 106 is performed to synthesis the nanolaminated structures 16. In the second stage 110, the bump 12 with the crystal seeds 15 already formed thereon is placed in the second solution containing the second metal ions for a redox reaction to occur. By controlling the reduction rate of the second metal ions, the second metal ions are reduced to a second metal, and grown on the crystal seeds 15, to form the second metal nanolaminated structures 16. In another exemplary embodiment, the second metal ions are silver ions, and the second solution containing the second metal ions also includes the ingredients of silver nitrate, ascorbic acid, and sodium hydroxide. The silver ions of silver nitrate are reduced by ascorbic acid to silver particles, which will grow on the crystal seeds to form silver nanolaminated structures. In this exemplary embodiment of the disclosure, instead of forming the nanometal particles directly on the organic layer 14 above the bump 12, the second metal ions are received on the organic layer 14 above the bump 12 and are reduced to second metal. Accordingly, the application of a large amount of protecting agent to prevent the aggregation of the nanoparticles is precluded. However, to prevent the aggregation of second metal ions and to also control the growing mechanism of the nanometal particles for the isotropic growing of the crystal seeds, a small amount of protecting agent may still be required. However, the required amount of the protecting agent is very small. The protecting agent, which includes, but not limited to, cetyltrimethylammonium bromide (CTAB) or polyvinylpyrrolidone (PVP), may be added to the second solution. In one exemplary embodiment, the mole ratio of silver nitrate to cetyltrimethylammonium bromide is, for example, less than 1:250. In another exemplary embodiment, the mole ratio of silver nitrate to cetyltrimethylammonium bromide is, for example, 1:250 to 1:750.

The nanolaminated structures formed according to the above the exemplary embodiment of the disclosure include nanowires, ball-shaped structures, flake-shaped structures, nanorods, nanocubes, structures with irregular shapes, or a combination thereof. The size of the second metal of the nanolaminated structures is, for example, 50 nm to 200 nm. In the exemplary embodiment as shown in FIG. 3C, the second metal ions are silver ions, and the silver ions in the second solution are reduced to silver, which is grown into silver nonlaminated structures 16 on the crystal seed.

Thereafter, as shown in FIG. 2, a cleaning step 112 is performed. Since the nanolaminated structures are grown in a solution, a very small amount of protecting agent is required. Further, only a very small amount of the protecting agent is remained on the surface of the nanolaminated structures 16 when the member 10 is removed from the solution. Accordingly, a complicated cleaning process for removing the protecting agent is precluded. The cleaning step may employ, for example, water or alcohol to perform the cleaning. Since a small amount of the protecting agent is used, even there are residuals, the formation of voids in the subsequent package process is mitigated; hence, the affect on contact resistance is small.

During the fabrication process of the above nanolaminated structures 16, the reduction rate is adjustable by manipulating the reaction conditions, such as the concentration of the second metal ions, the concentration of the protecting agent, and the concentration of the reducing agent. Further, by controlling of the reduction time, the formation of nanolaminated structures with different sizes, shapes, and densities is achieved. The details of the synthesis of a nanolaminated structure may be referred to “Wet Chemical Synthesis of Silver Nanorodes and Nanowires of Controllable Aspect Ratio” by Nikhil R. Jana, et al. in Chem. Commun., page 617-618 and is incorporated herein as reference.

The above member having a bump may directly bond with another member having a bump with a nanolaminated structure thereon without the application of a solder.

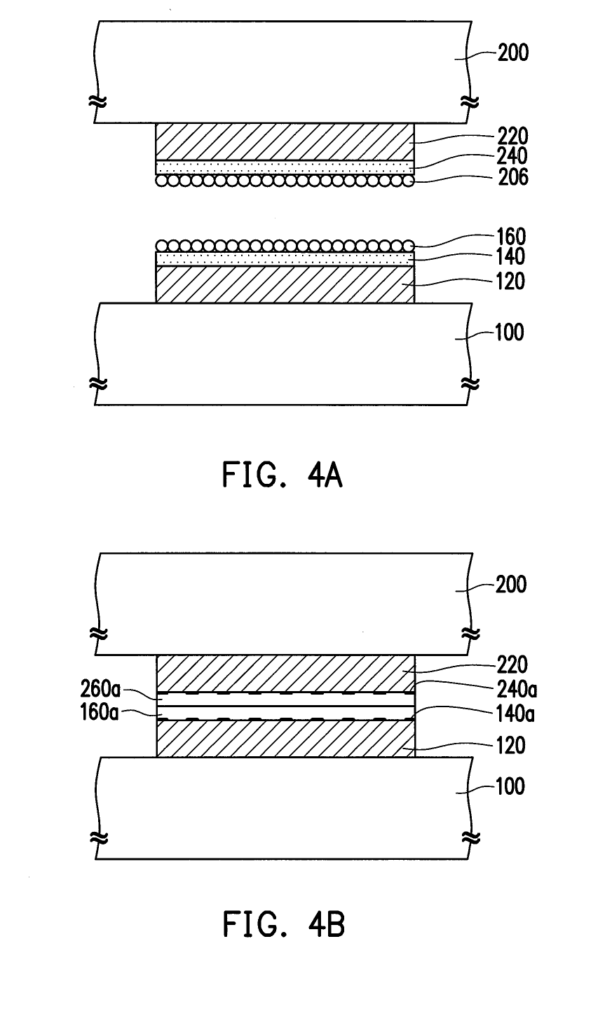

FIGS. 4A to 4B are schematic cross-sectional views of a packaging process according to an exemplary embodiment of the disclosure.

Referring to FIG. 4A, a first member 100 includes a first bump 120, an organic layer 140, and first nanolamianted structures 160 thereon. A second member 200 includes a second bump 220, a second organic layer 240, and second nanolaminated structures 260 thereon. The second member 200 and the first member 100 may constitute with the same or different materials. The first nanolaminated structures 160 and the second nanolaminated structures 260 may constitute with the same of different materials. Similarly, the first organic layer 140 and the second organic layer 240 may constitute with the same or different materials. The materials of the first member 100, the second member 200, the first nanolaminated structure 160, the second nanolaminated structure 260, the first organic layer 140, and the second organic layer 240 are similar to those described in the above exemplary embodiments and will not be further discussed herein.

Referring to FIG. 4B, thermal compression bonding is performed to tightly join the first bump 120 and the second bump 220 together. Since both the first bump 120 and the second bump 220 respectively include the first nanolaminated structures 160 and the second nanolaminated structures 260, and the dimensions of the metal particle diameter of the first nanolaminated structures 160 and the metal particle diameter of the second nanolaminated structures 260 are for example, 50 nm to 200 nm, in which the metals have large surface activity, the diffusion reaction of metal atoms could be accelerated. Therefore, a heating to the melting temperatures of the first nanolaminated structures 160 and the second nanolaminated structures 260 is precluded. In fact, diffusion bonding may be performed at a low temperature (approximately at ½ of the melting temperature of the first nanolaminated structures 160 and the second nanolaminated structures 260). Moreover, based on the high surface activity of the first nanolaminated structures 160 and the second nanolaminated structures 260, a high surface force being like adhesive force of gecko-foot-hair is provided. Accordingly, the applied pressure required in the thermal compression bonding process is greatly reduced. In one exemplary embodiment, the first nanolaminated structures 160 and the second nanolamianted structures 260 are respectively silver nanomaminated structures with a particle diameter of about 30 nm to 200 nm. The temperature of the thermal compression bonding process is performed at a temperature of about 200° C. to 400° C., and the pressure is about 20 MPa to about 200 MPa. Subsequent to the thermal compression bonding process, the first nanolaminated structures and the second nanolamianted structures 260 respectively form a first nanolaminated layer 160a and a second nanolaminated layer 260a. The first organic layer 140 and the second organic layer 240 degrade after the thermal compression bonding process, and the first nanolaminated layer 160a is in direct contact with the first bump 120, while the second nanolaminated layer 260a is in direct contact with the second bump 220. When the carbon number of the molecular chain of the first organic layer 140 and the second organic layer 240 is less than 10, small molecules that are formed after the degradation are mislaid and no degraded fragments remain. When the carbon number of the molecular chain of the first organic layer 140 and the second organic layer 240 is less than 10 and under the conditions that the contact resistance between the first nanolaminated layer 160a and the first bump 120 and the contact resistance between the second nanolamianted layer 260a and the second bump 220 are not being affected, voids may be formed in the nanolaminated structure subsequent to the degradation of the first organic layer 140 and the second organic layer 240. Alternatively speaking, the subsequently formed package structure includes, from bottom to top, a first member 100, a first bump 120, a first nanolaminated layer 160a, a second nanolaminated layer 260a, degraded fragments 240a of the second organic layer, a second bump 220, and a second member 200.

In the above exemplary embodiment, the two members respectively have a bump, an organic layer, and a nanolaminated structure. Moreover, the two members being bonded by a solder layer is used as an exemplary illustration. In another exemplary embodiment, one of the member includes a bump, an organic layer, and a nanolaminated structure, while another member includes a bump having the above nanolaminated structure thereon, wherein the bump and the nanolaminated structure do not include an organic layer therebetween.

### Exemplary Embodiments 1-6

An etching solution is used to clean the surface of the copper electrode to remove the oxide layer on the surface of the copper electrode. Pure water is then used to remove the etching solution remaining on the surface of the copper electrode. Thereafter, the copper electrode, already formed with HSC₂H₄COOH, is placed in an aqueous solution of silver nitrate, sodium borohydride, and PVP. The mole ratios of silver nitrate, sodium borohydride, and PVP in the exemplary embodiments are shown in Table 1, wherein the mole ratio of silver nitrate to PVP changes with the area of the copper electrode, for example, 1:0.05 to 1:0.5, and the mole ratio of silver nitrate to sodium citrate is, for example 1:0.5 to 1:3.

The particle diameters illustrated in Table 1 are the average particle diameters. Appropriate mixing is performed during the experiment to promote the growing of the seed and heating is occasionally required. After the completion of the reaction, water or alcohol is used to perform the cleaning.

### Exemplary Embodiment 7

An etching solution is used to clean the surface of the copper electrode to remove the oxide layer on the surface of the copper electrode. Pure water is then used to remove the etching solution remaining on the surface of the copper electrode. Thereafter, the copper electrode, already formed with HSC₂H₄COOH, is placed in 0.25 mM silver nitrate, 5 ml of 10 mM of sodium borohydride and 0.25 mM of sodium citrate for the redox reaction to proceed. The mole ratio of silver nitrate to sodium citrate is not limited to the ratio disclosed above; in one example, the ratio of silver nitrate to sodium citrate is about 1:0.5 to 1:3. After the reaction is completed, water or alcohol is used to perform the cleaning process. The resulting nanosilver structure has a small particle diameter of about 5 to 20 nm, for example. The previously formed copper electrode is placed in a mixture solution containing 50 ml of 80 mM cetyltrimethylammonium bromide (CTAB), 0.5 ml of 10 mM silver nitrate, 0.5 mL of 100 mM ascorbic acid, and 0.1 ml of 1M sodium hydroxide for a redox reaction to proceed. The mole ratio of silver nitrate to cetyltrimethylammonium bromide is not limited to the ratio disclosed above. In one example, the mole ratio of silver nitrate to cetyltrimethylammonium bromide is about 1:250 to 1:750. Appropriate mixing is performed during the experiments to promote the growing of the seed and heating is occasionally required. After the reaction is completed, water or alcohol is used to perform the cleaning.

TABLE 1

| | | | | | Size of |
|---|---|---|---|---|---|
| | | | | | Nano-silver |
| | AgNO₃ | PVP | NaBH₄ | Sodium Citrate | Structure |
| | (mM) | (mM) | (mM) | (mM) | (nm) |
| Example 1 | 1 | 0.01 | 0.5 | 0 | 74.0 |
| Example 2 | 1 | 0.1 | 0.154 | 0 | 104 |
| Example 3 | 1 | 0.02 | 0.77 | 0 | 86.2 |
| Example 4 | 1 | 0.04 | 1.54 | 0 | 62.6 |
| Example 5 | 1 | 0.06 | 1.54 | 0 | 145 |
| Example 6 | 1 | 0 | 40 | 1 | 30 |
| Example 7 | 1 | 0.06 | 1.5 | 0 | 31.3 |

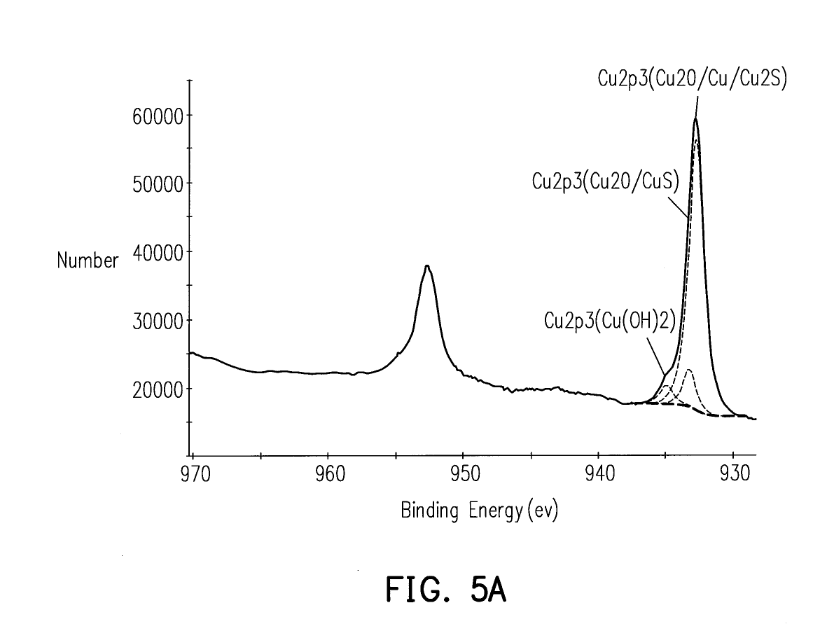

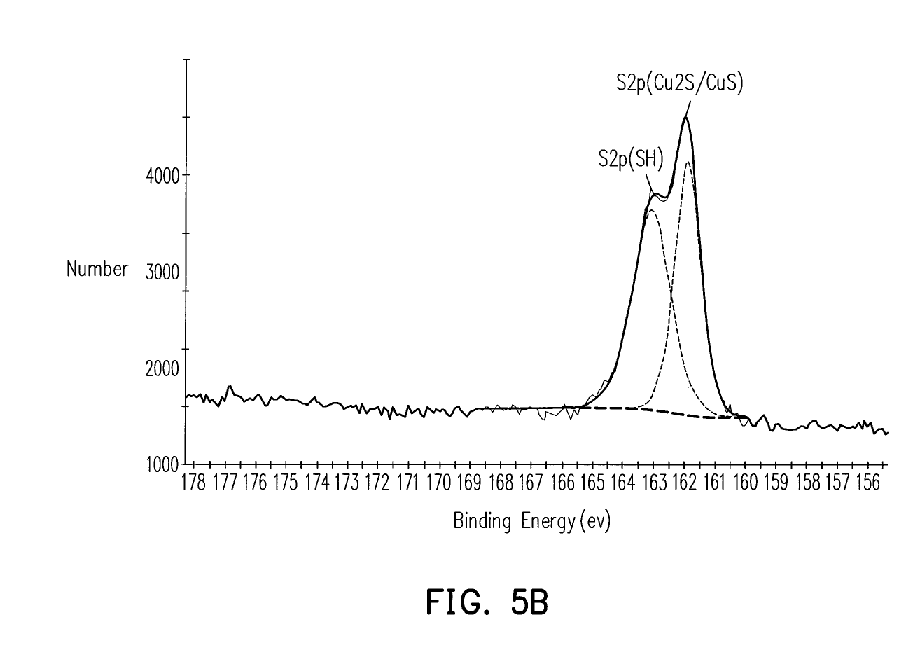

FIGS. 5A to 5B are spectra of the ESCA analysis respectively showing the copper curve and the sulfur curve according an exemplary embodiment of the disclosure. The results in FIGS. 4A and 4B suggest that a Cu—S bond is generated between the SH terminal of HSC₂H₄COOH and copper. Similarly, silver ions react to form a bond with the COOH terminal of HSC₂H₄COOH.

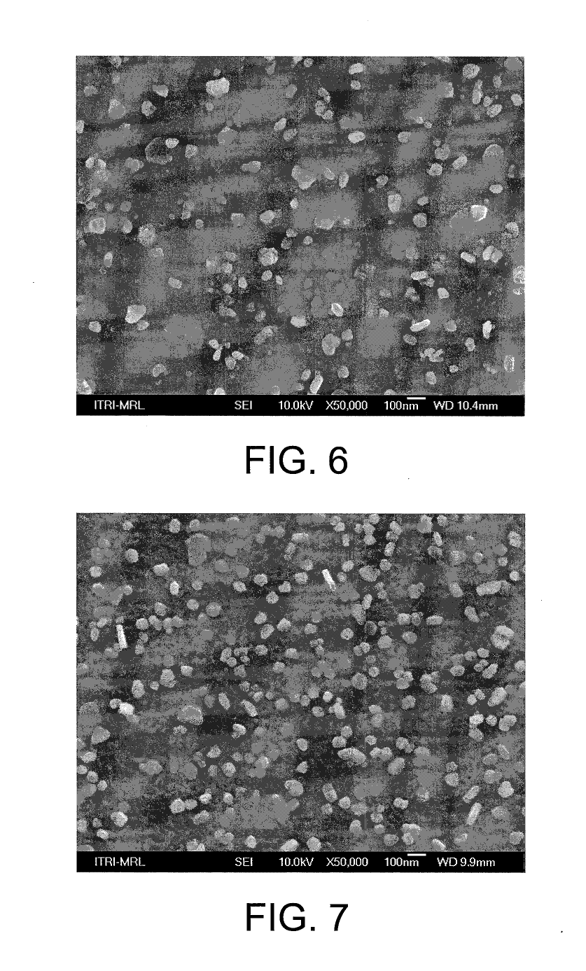

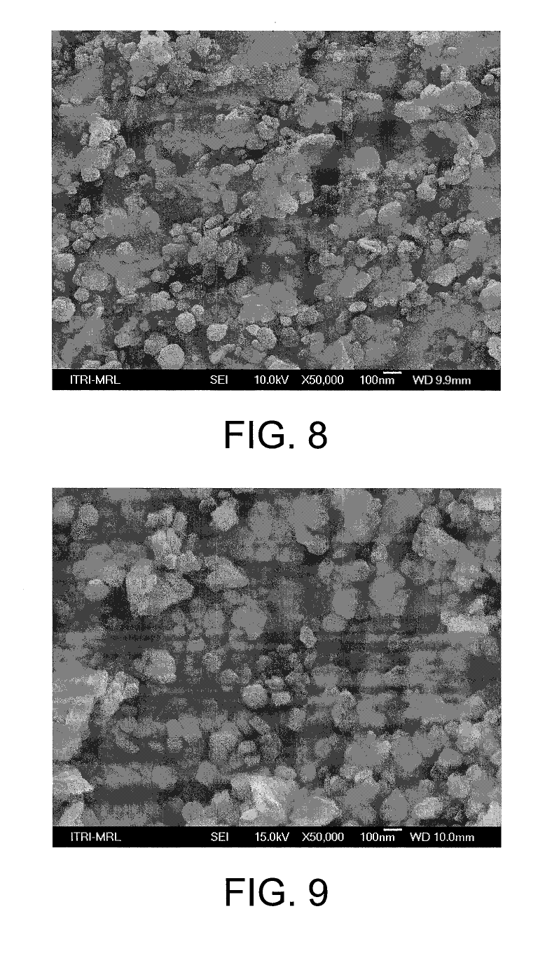

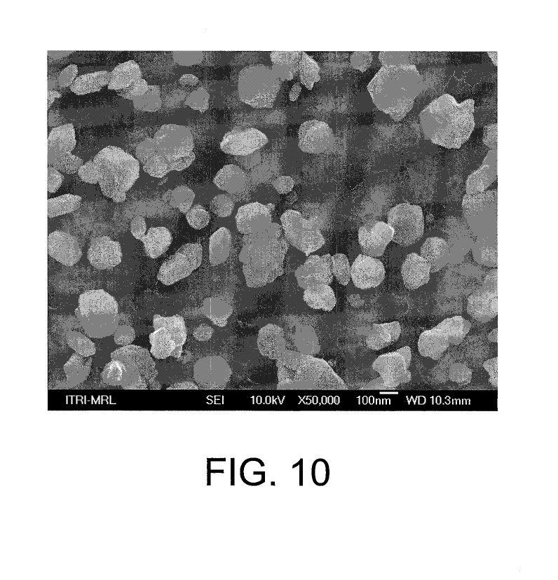

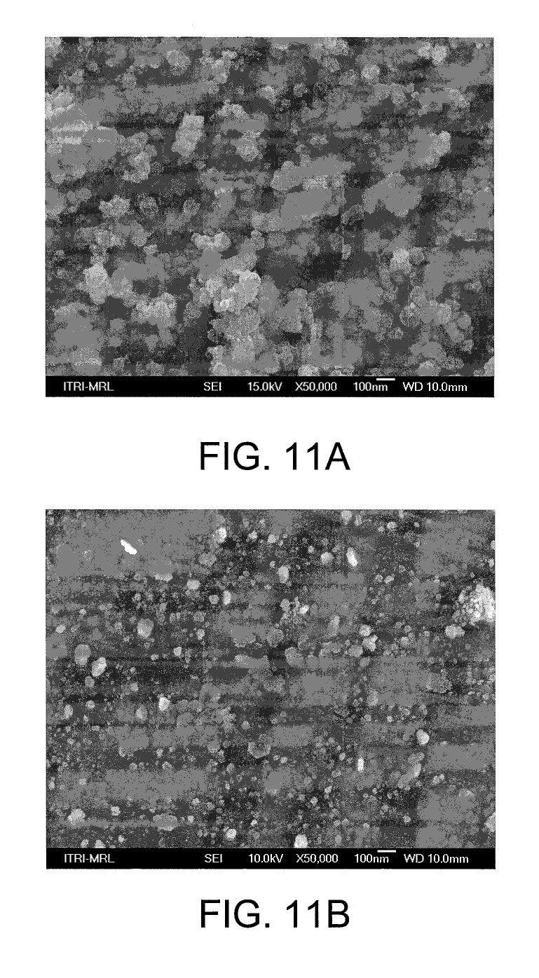

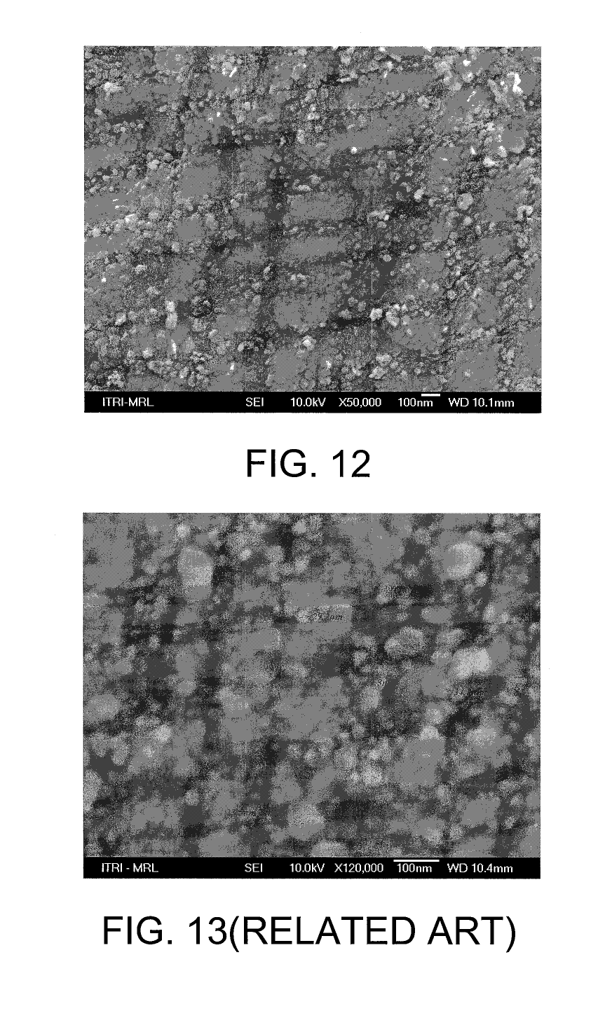

The dimensions of the nanoparticles synthesized in the above Examples 1-7 are summarized in Table. Pictures from scanning electron microscope (SEM) of the above Examples 1-5, 6 and 7 are respectively presented in FIGS. 6-10, 11A, 11B and 12. According to the results shown in Table 1 and FIGS. 6 to 12, through the modification of the formulation, the metal ions on the bump are reduced to nanometals of different sizes and shapes. The nanometals synthesized in Example 7 have a rod shape or a flake shape as shown in FIG. 12. Moreover, as clearly shown in 11A, the nanometals are stacked to form the nanolaminated structure, and the situation of which the nanolaminated structures being enclosed by the protecting agent is not being observed in the SEM pictures. The current results are different from those obtained from the conventional method.

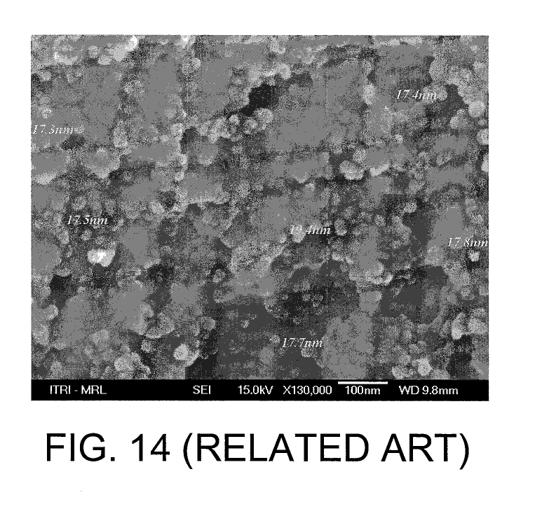

FIGS. 13 and 14 are scanning electron microscope pictures respectively showing the application of various amounts of the protecting agent for the disposition the nanoparticles directly on a substrate according to the prior art. In the prior art, the nanometals are placed directly on the substrate. To disperse and to avoid the aggregation of the protecting agent (protecting group), the amount of the protecting agent increases correspondingly as the dimension of the nanometals decreases. In the SEM pictures shown in FIGS. 13 and 14, the bump with the nanometals are fabricated, according to the conventional method, with the protecting agents respectively formed with 4 to 6 weight percent of PVP and 8 to 10 weight percent of PVP. Based on the results shown in FIGS. 13 and 14, the peripheries of the metal groups are enclosed by a group of substance, and the group of substance is the protecting agent.

According to the exemplary embodiments of the disclosure, the organic layer has a bifunctional group, which selectively bonds with metal ions through chemical or physical bonding and allows the metal ions to reduce to metal directly on the bump to form a dense nanolaminated structure.

According to the packaging structure of the exemplary embodiment of the disclosure, at least one of the two members includes an organic layer. Further, by using one terminal function group of the organic molecule of the organic layer, the organic layer is selectively bonded with the bump via chemical or physical bonding. Another terminal functional group is bonded with the metal ions in the solution. The metal ions are further reduced to a metal via a redox reaction to form a dense nanolaminated structure. Because of the low melting point characteristic of the nonmetals, a low temperature bonding is performed. Although voids may form between the nanomainated structure and the bump or in the nanolamianted structure after the degradation of the organic layer, desirable bonding between the nanometals and the bump is still achieved.

According to the fabrication method of a bump having a nanolamianted structure, wherein by relying on the formation of an organic layer and the occurrence of a redox reaction, metal ions are reduced to metals, and dense nanolaminated structures are formed on a bump.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A bump having a nanolaminated structure, the bump comprising:
a plurality of nanometals configured on a bump, the plurality of nanometers constituting the nanolaminated structure; and
an organic layer, contiguous to the bump and the nanolamiated structure, the organic layer having a structure of G₁-R-G₂, wherein
R is alkylene having less than 10 carbons;
G₁ is a first functional group and is bonded with a first metal atom of the bump; and
G₂ is a second functional group and is bonded with a second metal atom of the nanolaminated structure.

2. The bump having the nanolaminted structure of claim 1, wherein the plurality of nanometals comprises gold, silver, copper, platinum, nickel, an alloy thereof, or a composite thereof.

3. The bump having the nanolaminted structure of claim 1, wherein the first functional group comprises one of 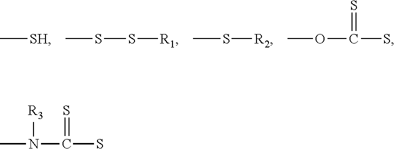
wherein R₁, R₂ and R₃ are each independently an alkyl with or without a substituted group, and the substituted group includes carboxyl (—COOH), amino (—NH₂), amide (—CONH₂), cyano (—CN), —OH, —Si—OH, or —Si(OCₓH₂ₓ₊₁)₃, wherein x is 1, 2, or 3.

4. The bump having the nanolaminted structure of claim 1, wherein the second functional group includes carboxyl (—COOH), amino (—NH₂), amide (—CONH₂), cyano (—CN), hydroxyl (—OH), silicon hydroxyl (—Si—OH), or —Si(OCₓH₂ₓ₊₁)₃, and x is 1, 2, or 3.

5. The bump having the nanolaminted structure of claim 1, wherein a material of the organic layer comprises HS—(CH₂)ₙ—COOH or HS—(CH₂)ₙ—Si(OCₓH₂ₓ₊₁)₃, wherein n is a whole number ranging from 1 to 10, x is 1, 2, or 3, OCₓH₂ₓ₊₁ is totally or partially hydrolyzed into —OH.

6. The bump having the nanolaminted structure of claim 1, a dimension of the bump is greater or equal to 1 micron, and a size of each nanometer is about 50 nanometer to about 200 nanometer.

7. The bump having the nanolaminted structure of claim 1, wherein the plurality of nanometers comprises nanowires, ball-shaped structures, flake-shaped structures, nanorods, nanocubes, structures with irregular shapes, or a combination thereof.

8. The bump having the nanolaminted structure of claim 1, a thickness of the nanolaminated structure is less than 1 micron.

9. The bump having the nanolaminted structure of claim 1, wherein a material of the bump comprises gold, silver, copper, platinum, nickel, an alloy thereof, or a composite thereof.

10. A package structure, comprising:
a first member;
a first bump, positioned on the first member;
a first nanolamianted layer, configured on and electrically connected with the first bump;
a fragment of a first organic layer, configured between the first bump and the first nanolaminated layer, the first organic layer has a structure of G₁-R-G₂, wherein
R is alkylene having less than 10 carbons;
G₁ is a first functional group, comprising one of 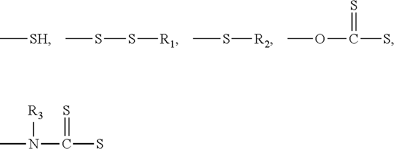
wherein R₁, R₂ and R₃ are each independently an alkyl with or without a substituted group, and the substituted group includes carboxyl (—COOH), amino (—NH₂), amide (—CONH₂), cyano (—CN), —OH, or —Si—OH; and
G₂ is a second function group, comprising one of carboxyl (—COOH), amino (—NH₂), cyano (—CN), —OH, —Si—OH, and —CHO;
a second member, configured opposite to the first member;
a second bump, configured on the second member; and
a second nanolaminated layer, configured between and electrically connected with the first nanolaminated layer and the second bump.

11. The package structure of claim 10, wherein the first bump and the first nanolaminated layer are constituted with different materials, and the first functional group and the second functional group are different.

12. The package structure package structure of claim 10, wherein a thickness of the first nanolaminated layer is less than 1 micron.

13. The package structure of claim 10 further comprising a fragment of a second organic layer, configured between the second bump and the second nanolaminated layer, the second organic layer has a structure of G₁′—R′-G₂′, wherein
R′ is alkylene having less than 10 carbons;
G₁′ is a third functional group, comprising one of 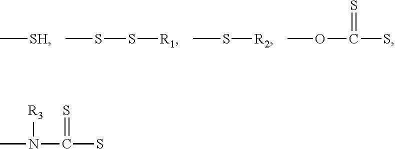
wherein R₁, R₂ and R₃ are each independently an alkyl with or without a substituted group, and the substituted group includes carboxyl (—COOH), amino (—NH₂), amide (—CONH₂), cyano (—CN), —OH, —Si—OH, or —Si(OCₓH₂ₓ₊₁)₃, and x is 1, 2, or 3; and
G₂′ is a fourth functional group, comprising one of carboxyl (—COOH), amino (—NH₂), —OH, cyano (—CN), —Si—OH, —CHO, and —Si(OCₓH₂ₓ₊₁)₃, wherein x is 1, 2, or 3.

14. The package structure of claim 10, wherein a thickness of the second nanolaminated layer is less than 1 micron.

15. A fabrication method of a bump having a nanolaminated structure, the fabrication method comprising:
providing a surface comprising at least a bump thereon;
performing a first self-assembling step, a organic layer self-assembling on the bump, wherein the organic layer comprises a structure of G₁-R-G₂, wherein
R is alkylene having less than 10 carbons;
G₁ is a first functional group and is bonded with a first metal atom of the bump, the first function group comprises one of: 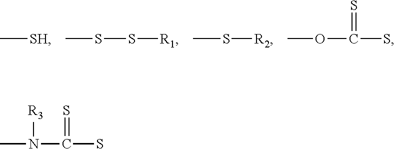
wherein R₁, R₂ and R₃ are each independently an alkyl with or without a substituted group, and the substituted group includes carboxyl (—COOH), amino (—NH₂), amide (—CONH₂), cyano (—CN), —OH, —Si—OH, or —Si(OCₓH₂ₓ₊₁)₃, and x is 1, 2, or 3; and
G₂ is a second functional group and is exposed, and the second functional group is different from the first functional group and comprises carboxyl (—COOH), amino (—NH₂), amide (—CONH₂), cyano (—CN), —OH, —Si—OH, or —Si(OCₓH₂ₓ₊₁)₃, wherein x is 1, 2, or 3.
performing a second self-assembling step, wherein the second metal ions bond on the bump through the organic layer;
performing a redox reaction to reduce the second ions to a second metal to form a plurality of nanolaminated metals; and
forming a nanolaminted structure by stacking the plurality of the nanolaminated metals.

16. The fabrication method of claim 15, wherein a material of the organic layer comprises HS—(CH₂)ₙ—COOH or HS—(CH₂)ₙ—Si(OCₓH₂ₓ₊₁)₃, wherein n is a whole number ranging from 1 to 10, x is 1, 2 or 3, and OCₓH₂ₓ₊₁ is totally or partially hydrolyzed into —OH.

17. The fabrication method of claim 15, wherein the second self-assembling step comprises:
placing the bump having the organic layer already formed thereon in a first solution to form a plurality of crystal seeds on the organic layer; and
placing the bump having the plurality of crystal seeds already formed thereon in a second solution for the plurality of crystal seeds to grow into the plurality of nanolaminated metals stacked together.

18. The fabrication method of claim 17, wherein the second solution comprises silver nitrate, ascorbic acid, and sodium hydroxide.

19. The fabrication method of claim 17, wherein the second solution further comprises a protecting agent.

20. The fabrication method of claim 19, wherein the protecting agent comprises cetyltrimethylammonium bromide (CTAB) or polyvinylpyrrolidone (PVP).

21. The fabrication method of claim 15, the bump and the surface are constituted with different materials.

22. The fabrication method of claim 21, wherein the bump comprises gold, silver, copper, platinum, nickel, an alloy thereof, or a composite thereof.

23. The fabrication method of claim 15 further comprising performing a cleaning step.
